(19) United States
(12) Patent Application Publication
(10) Pub. No.: US 2024/0105879 A1
(43) Pub. Date: Mar. 28, 2024

(54) LIGHT-EMITTING DIODE AND MANUFACTURING METHOD THEREOF

(71) Applicant: Quanzhou sanan semiconductor technology Co., Ltd., Fujian (CN)

(72) Inventors: TSUNG-MING LIN, Fujian (CN); CHUNG-YING CHANG, Fujian (CN); YI-JUI HUANG, Fujian (CN); YU-TSAI TENG, Fujian (CN)

(73) Assignee: Quanzhou sanan semiconductor technology Co., Ltd., Fujian (CN)

(21) Appl. No.: 18/523,728

(22) Filed: Nov. 29, 2023

Related U.S. Application Data
(63) Continuation-in-part of application No. PCT/CN21/97811, filed on Jun. 2, 2021.

(51) Int. Cl. H01L 33/00

(52) U.S. Cl. CPC H01L 33/0095

(57) ABSTRACT

A light-emitting diode and a manufacturing method thereof are provided. The manufacturing method includes following steps. First, an LED wafer is provided. The LED wafer includes a substrate and a light-emitting semiconductor stacking structure positioned on the surface of the substrate. The light-emitting semiconductor stacking structure includes a first type semiconductor layer, an active layer, and a second type semiconductor layer from a side of the substrate. Second, dicing lanes are defined on the upper surface of the LED wafer. Third, dicing is performed along the dicing lanes of the substrate using a laser. The laser is focused on the lower surface of the substrate to form a surface hole and focused inside the substrate to form an internal hole. The diameter of the surface hole is greater than the diameter of the internal hole. Fourth, the LED wafer is separated into LED chips along the dicing lanes.

### CROSS-REFERENCE TO RELATED APPLICATION

This application is a continuation-in-part of international PCT application serial no. PCT/CN2021/097811, filed on Jun. 2, 2021. The entirety of the above-mentioned patent application is hereby incorporated by reference herein and made a part of this specification.

### BACKGROUND

### Technical Field

The invention relates to the field of semiconductor technology, specifically a light-emitting diode and a manufacturing method thereof.

### Description of Related Art

A light-emitting diode (LED) is a semiconductor device that emits light using the energy released when carriers recombine. In particular, flip-chip LED chips are increasingly used due to the low energy consumption, long life, energy saving and environmental protection.

In the manufacturing process of traditional LED chips, laser dicing is usually used to form a series of laser scratches inside the sapphire substrate of the LED wafer, as shown in FIG. 1; then the splitting method is used to dice the LED wafer to form LED chips, as shown in FIG. 2. The appearance of the LED chip after dicing and splitting using the above method has oblique angles and irregular cracks. FIG. 3 shows the oblique cracking of the LED chip manufactured by the traditional method. FIG. 4 shows the chipping of edges and corners on the back in the photo.

### SUMMARY

Therefore, the purpose of the invention is to provide a light-emitting diode and a manufacturing method thereof that can overcome at least one disadvantage of the prior art.

In some embodiments, the invention provides a manufacturing method of a light-emitting diode that includes the following steps.

First, an LED wafer is provided, the LED wafer includes a substrate and a light-emitting semiconductor stacking structure positioned on an upper surface of the substrate, and the light-emitting semiconductor stacking structure includes a first type semiconductor layer, an active layer, and a second type semiconductor layer from a side of the substrate;

Second, dicing lanes are defined on an upper surface of the LED wafer.

Third, dicing is performed along the dicing lanes of the substrate using a laser: the laser is focused on a lower surface of the substrate to form a surface hole, the laser is focused inside the substrate to form an internal hole, and a diameter of the surface hole is greater than a diameter of the internal hole.

Fourth, the LED wafer is separated into multiple LED chips along the dicing lanes.

In the manufacturing method of the light-emitting diode, the diameter of the surface hole formed on the surface of the substrate is preferably greater than the diameter of the internal hole, which can properly control the chipping of edges and corners from the LED splitting, and a square LED chip is obtained. In a specific embodiment, the diameter of the surface hole is 5 to 15 μm, the diameter of the internal hole is 3 to 5 μm, and the angle between a side surface of the substrate and the upper and lower surfaces of the substrate is 90±2°.

In some embodiments, preferably, a spacing is kept between the surface hole and the internal hole of the substrate without dicing through the surface or dicing through inside after the surface is diced, so as to prevent the heat energy generated during the laser dicing process from damaging the epitaxial layer of the chip and causing the electrical leakage phenomenon.

Preferably, the depth of the surface holes formed in the third step is 1/10 to ⅕ of the thickness of the substrate, the length of the internal hole is ⅓ to ⅔ of the distance from a first surface of the substrate to the bottom of the surface hole, which is beneficial to controlling the oblique crack directions and oblique crack forms of the LED wafer splitting.

Preferably, the dicing lanes defined in the second step includes a first direction and a second direction, the first direction is perpendicular to the second direction. In the third step, X scribe lines are formed on the same cross-section inside the substrate along the first direction using a first laser beam, and Y scribe lines are formed on the same cross-section inside the substrate along the second direction using a second laser beam, in which a pulse energy of the first laser beam is greater than a pulse energy of the second laser beam. During the dicing process, dicing marks are formed on different side surfaces using different laser energies. For example, for the dicing surface positioned at the hard-to-crack surface, a laser beam with a large pulse energy is used to form a large modified portion inside the substrate to ensure that the subsequent splitting is carried out smoothly, for the dicing surface positioned at the easy-to-crack surface, a laser beam with a small pulse energy is used to form a small modified portion inside the substrate, so as to avoid damaging the epitaxial layer during the laser etching process and to prevent the cracks from extending to the upper surface of the substrate during the splitting process, resulting in damages to the semiconductor stacking structure, the insulation layer, or the electrode, and causing the failure of the chip.

The values of X and Y are selected according to the thickness of the substrate. For example, in some embodiments, the thickness of the substrate is 200 μm or less, and the values may be as follows: 1≤X≤5, 2≤Y≤20; in other embodiments, the thickness of the substrate is 200 to 750 μm, and the values may be as follows: 2≤X≤9, 5≤Y≤50.

In some embodiments, the thickness of the substrate is less than or equal to 200 μm. It is preferable to adopt a single-blade multi-focus method to form a scribe line inside the substrate. This way, on the one hand, the split appearance of double cracks can be avoided, and on the other hand, the efficiency of laser dicing can be improved.

In some embodiments, Y>X≥1, that is, to form different quantities of laser etching patterns on different side surfaces of the substrate, for example, forming a small quantity of laser etching patterns on the dicing surface of the hard-to-crack surface, which is beneficial to forming a large modified portion inside the substrate using the laser beam with a large pulse energy, so as to prevent the light spot of the laser beam from irradiating the epitaxial layer or prevent the dicing marks from extending to the light-emitting epitaxial structure that damages the epitaxial structure or the electrode and causing the failure of the chip. A large quantity of dicing marks (such as 5 to 20) are formed on the dicing surface of the easy-to-crack surface. On the one hand, vertical destruction is performed at multiple points on the (1102) surface in the lattice direction, so as to prevent the cracks from cracking along the direction of the slip surface (1102) during the subsequent splitting process, and a substantially vertical side wall is obtained, on the other hand, it is beneficial to form a fine concave-convex structure on the side wall of the substrate to increase the light extraction efficiency of the side surface of the LED chip.

Preferably, the distance between the focus point of the laser beam inside the substrate and the upper surface of the substrate is greater than or equal to 10 μm, so as to prevent the laser dicing process or the splitting process from damaging functional layers of the LED chip that causes electrical leakage.

The invention also provides a light-emitting diode, which includes a substrate and a light-emitting semiconductor stacking structure positioned on the upper surface of the substrate. The light-emitting semiconductor stacking structure includes a first type semiconductor layer, an active layer, and a second type semiconductor layer from a side of the substrate. At least one side surface of the substrate includes a surface laser etching pattern and an internal laser etching pattern, the surface laser etching pattern is a series of recesses extending from the lower surface of the substrate to the upper surface, the internal laser etching pattern includes a series of connected or non-connected explosion spots formed by laser etching, and the diameters of the recesses perpendicular to the thickness direction is greater than the diameters of the explosion spots perpendicular to the thickness direction.

In some embodiments, the substrate is a crystal structure, which includes a first side surface and a second side surface adjacent to each other, the first side surface has X first dicing marks formed by laser dicing, and the second side surface has Y second dicing marks formed by laser dicing, in which the roughness of the texture of the first dicing marks is greater than the roughness of the texture of the second dicing marks. Forming rough dicing marks on the hard-to-crack surface of the substrate is on the one hand beneficial to perform dicing, and on the other hand beneficial to improving the light extraction efficiency. Forming fine dicing marks on the easy-to-crack surface can avoid generating a large internal stress, thereby reducing the risk that the cracks occurred during the splitting process to reach the first surface of the substrate and damage the functional layers of the LED chip.

In some embodiments, the substrate is a crystal structure, which includes a first side surface and a second side surface adjacent to each other, in which the second side surface is the easy-to-crack surface, comprising Y dicing marks arranged in parallel formed by laser etching, in which the size of the dicing marks in the first column close to a side of the light-emitting semiconductor stacking structure is smaller than the dicing marks in other columns. By controlling the size of the dicing marks close to the side of the light-emitting semiconductor stacking structure to be smaller than the dicing marks therebelow, the dicing marks may be prevented from being affected by the external force during the splitting process, causing the crack to extend to the light-emitting epitaxial structure, thereby damaging the epitaxial structure.

In some embodiments, the substrate is a crystal structure, which includes a first side surface and a second side surface adjacent to each other, in which the first side surface is the hard-to-crack surface and includes at least three first dicing marks formed by laser dicing. The adjacent first dicing marks are non-connected or connected, but basically are not intersected with each other.

### BRIEF DESCRIPTION OF THE DRAWINGS

FIG. 1 and FIG. 2 show a traditional dicing method for LED chips, in which FIG. 1 shows dicing performed by using a laser to focus inside a sapphire substrate.

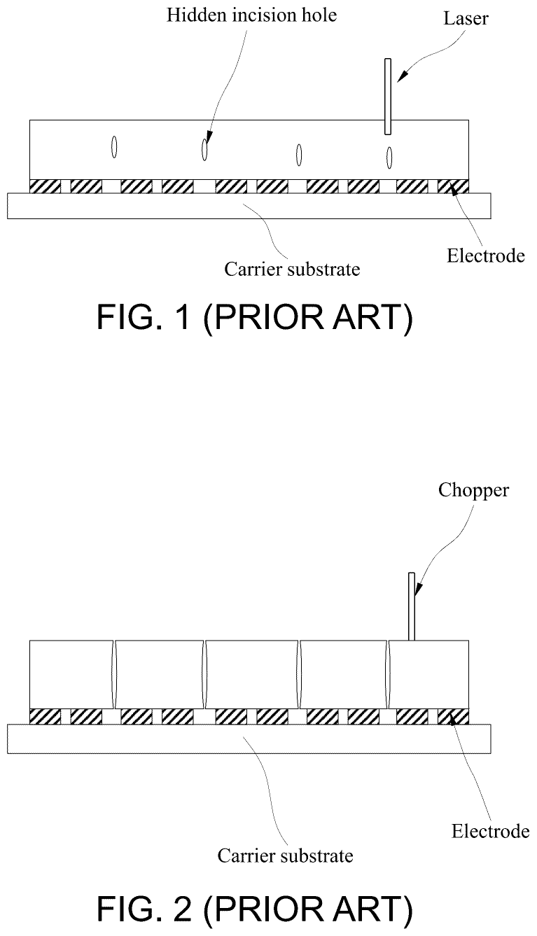

FIG. 2 shows splitting performed by using a chopper to form LED chips.

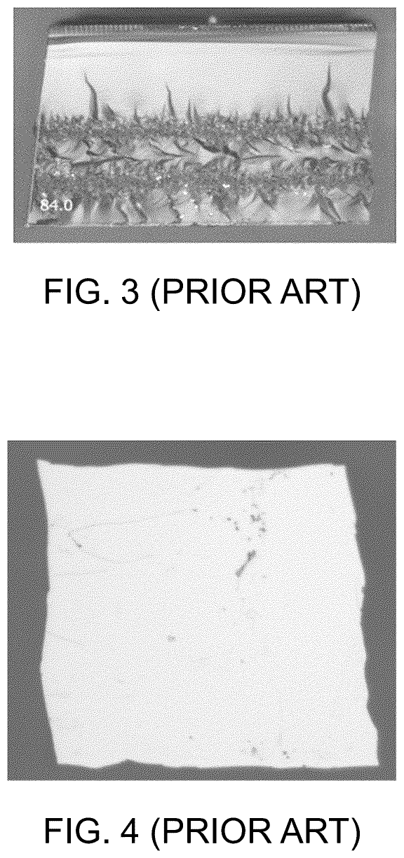

FIG. 3 shows a photo of an LED chip formed by the manufacturing method shown in FIG. 1 and FIG. 2, which shows the oblique cracking of the LED chip.

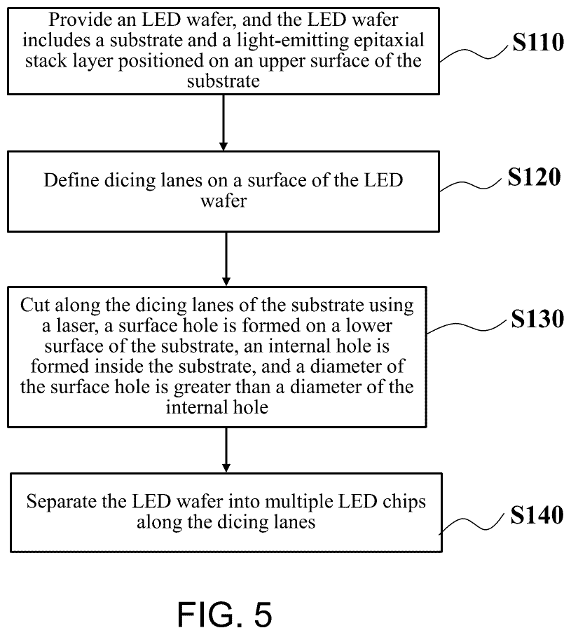

FIG. 4 shows a photo of the back of the LED chip formed by the manufacturing method shown in FIG. 1 and FIG. 2, which shows the chipping of edges and corners of the LED chip.

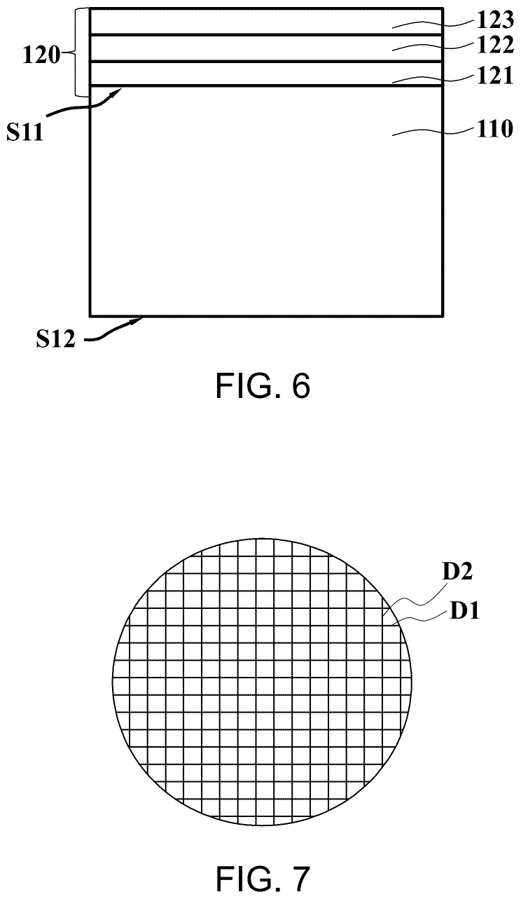

FIG. 5 shows a manufacturing flow chart of an LED chip implemented according to the invention.

FIG. 6 to FIG. 14 are structural schematic diagrams of the manufacturing flow of the LED chip described in FIG. 5. FIG. 6 shows a side cross-sectional view of an LED epitaxial structure; FIG. 7 shows defining the LED chip size and dicing lanes in the epitaxial structure shown in FIG. 6, and FIG. 8 concisely shows the formation of surface holes and internal holes on the surface and inside the substrate respectively; FIG. 9 shows the distribution of the surface holes and the internal holes formed along a first direction along the dicing lanes of the substrate by using a laser beam, and FIG. 10 shows the distribution of the surface holes and the internal holes formed along a second direction along the dicing lanes of the substrate by using the laser beam; FIG. 11 shows a top view of the LED chip formed by splitting; FIG. 12 shows a laser dicing pattern formed on a first side surface (corresponding to a first direction) of the substrate after the splitting; FIG. 13 shows a laser dicing pattern formed on a second side surface (corresponding to a second direction) of the substrate after the splitting; FIG. 14 shows a photo of the LED chip formed by splitting the LED wafer.

FIG. 15 shows a light distribution curve diagram of the LED chip formed according to the manufacturing method.

FIG. 16 shows another light-emitting diode implemented according to the invention.

FIG. 17 shows another light-emitting diode implemented according to the invention.

### DESCRIPTION OF THE EMBODIMENTS

### Embodiment 1

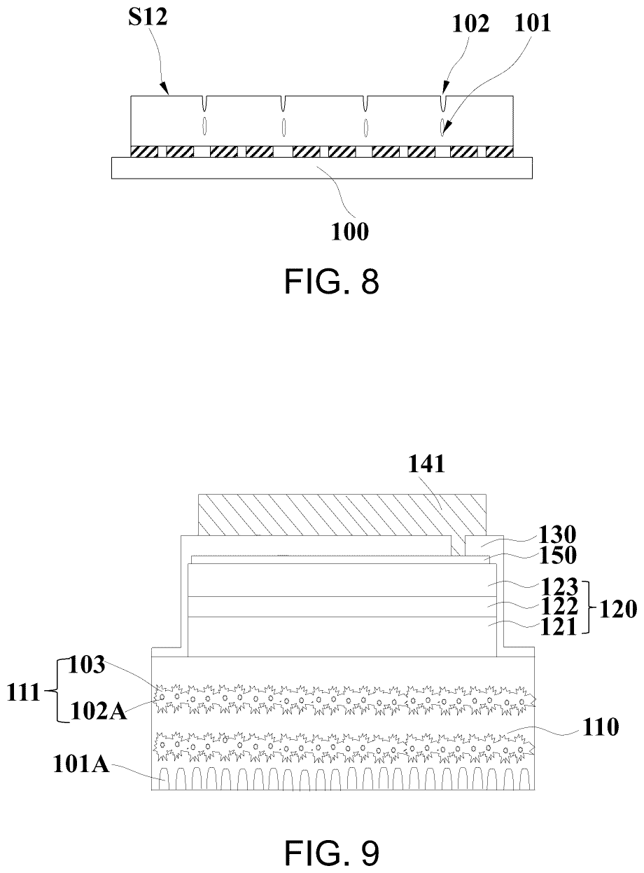

This embodiment discloses the following manufacturing method of an LED chip and the LED chip formed by using the manufacturing method, which uses lasers of different powers to perform multi-focus stealth dicing on different crystal surfaces, in which stealth dicing of dense and small multi-points is used for the crystal surface close to the slip surface to form approximately continuous multi-point dicing, which prevents the cracks from cracking along a (1102) surface during the splitting process. FIG. 5 shows the flow of the manufacturing method, which mainly includes Steps S110 to S140 below. The following will be described in detail along with FIG. 7 to FIG. 14.

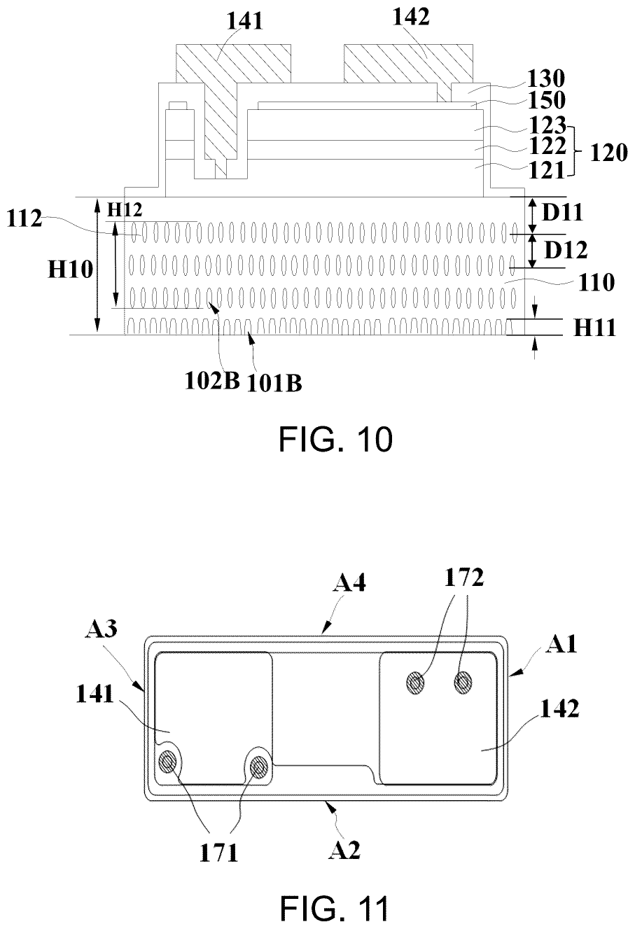

Step S110: an LED wafer is provided, and the LED wafer includes a substrate 110 and a light-emitting semiconductor stacking structure 120 positioned thereon, as shown in FIG. 6. Specifically, the substrate 110 is preferably a transparent or translucent material. The light emitted by the light-emitting semiconductor stacking structure 120 may be emitted outward through the substrate 110, and the substrate 110 is a growth substrate used for the growth of the light-emitting semiconductor stacking structure 120, such as a sapphire substrate, a GaN substrate, an AlN substrate. The substrate 110 includes a first surface S11, a second surface S12, and side walls, in which the first surface and the second surface are opposite to each other, and the substrate 110 may include a plurality of protrusions formed on at least a portion of the area of the first surface. For example, the substrate 110 may be a patterned sapphire substrate. The light-emitting semiconductor stacking structure may be formed on the substrate 110 through methods such as physical vapor deposition (PVD), chemical vapor deposition (CVD), epitaxy growth technology, and atomic layer deposition (ALD).

Generally, the light-emitting semiconductor stacking structure includes a first conductivity type semiconductor layer 121, an active layer 122, and a second conductivity type semiconductor layer 123. A specific light-emitting semiconductor stacking structure may include a III-V type nitride-based semiconductor, for example, a nitride-based semiconductor such as (Al, Ga, In)N, a phosphide semiconductor including (Al, Ga, In)P, or an arsenide-based semiconductor including (Al, Ga, In) As. The first conductivity type semiconductor layer 121 may include n-type impurities (e.g., Si, Ge, Sn), and the second conductivity type semiconductor layer 123 may include p-type impurities (e.g., Mg, Sr, Ba). Furthermore, the impurity types may also be reversed. The active layer 122 may include a multiple quantum well structure (MQW) to emit a desired wavelength by adjusting the element composition ratio of the semiconductor. In this embodiment, the second conductivity type semiconductor layer 123 may be a p-type semiconductor layer.

Step S120: dicing lanes are defined on the surface of the LED wafer. Specifically, the dicing lanes include a first dicing lane of a first direction D1 and a second dicing lane of a second direction D2 that are perpendicular to each other. The substrate 110 is a crystal structure, in which the first surface S11 of the substrate 110 is a C plane, and the crystal structure includes a slip surface at a certain angle with the C plane, in which the crystal surface corresponding to the second direction D2 is perpendicular to the C plane and close to the slip plane. In a specific embodiment, the substrate is of sapphire material, in which the first direction D1 corresponds to the hard-to-crack surface of the sapphire crystal, and the second direction D2 corresponds to the easy-to-crack surface of the sapphire crystal. The LED wafer is separated into a series of light-emitting units through the dicing lanes, and an electrode area is defined on each light-emitting unit. Through one photomask or multiple photomasks, the second conductivity type semiconductor layer 123 and the active layer 122 in the electrode area are etched to expose a portion of the surface of the first conductivity type semiconductor layer 121, and the second conductivity type semiconductor layer 123, the active layer 122, and the first conductivity type semiconductor layer 121 in the dicing lane area are etched to the first surface S11 of the substrate 110.

Further, an insulation layer 130 is covered on the surface and side walls of the exposed light-emitting semiconductor stacking structure. In existing coating processes, such as evaporation or sputtering coating, due to the shadow effect, the thickness of the insulation layer 130 on the side walls of the light-emitting semiconductor stacking structure is usually lower than the thickness of the insulation layer 130 on the top surface of the light-emitting semiconductor stacking structure and on the first surface of the substrate, which causes that the thickness of the light-emitting semiconductor stacking structure on the side walls is 40 to 90% of the thickness of the light-emitting semiconductor stacking structure on the top surface of the semiconductor sequence. In a specific embodiment, a contact electrode 150 is first formed on the surface of the second conductivity type semiconductor layer 123, in which the material may be ITO, GTO, GZO, ZnO, or a combination of the above, and then the insulation layer 130 is formed. A first electrode 141 and a second electrode 142 are manufactured on the insulation layer through photolithography and evaporation processes. The minimum horizontal spacing between the first electrode 141 and the second electrode 142 on the insulation layer 130 is preferably 5 μm or more, for example, the spacing may be 20 to 40 μm, 40 to 60 μm, or 60 to 80 μm, and the material may be a combination of metal such as Cr, Pt, Au, Ti, Ni, and Al. Preferably, the electrode has a multi-layer structure, and a surface layer thereof is preferably made of Au material. The first electrode 141 is electrically connected to the first conductivity type semiconductor layer 121 through an opening structure 171 that penetrates the insulation layer 130, and the second electrode 142 is electrically connected to the contact electrode 150 through the opening structure 172 that penetrates the insulation layer 130.

Step S130: The laser is used to dice along the dicing lanes of the substrate 110, surface holes 101 are formed on the lower surface of the substrate 110, and internal holes 102 are formed inside the substrate 110, and a spacing is preferably between the surface hole 101 and the internal hole 102, as shown in FIG. 8. In some specific implementations, the substrate 110 is first thinned to a target thickness of 80 to 200 μm, and then laser etching is performed. Controlling the depths of the surface holes 101 and the internal holes 102 is beneficial to controlling the oblique crack directions and oblique crack forms of the LED wafer splitting. The depth of the surface hole 101 is preferably 1/10 to ⅕ of the thickness of the thinned substrate, and the length of the internal hole 102 is ⅓ to ¾ of the distance from the first surface S11 of the substrate 110 to the bottom of the surface hole 101, which is beneficial to controlling the oblique crack directions and oblique crack forms of the LED wafer splitting. In this embodiment, the diameter of the surface hole 101 is preferably greater than the diameter of the internal hole 102, which can properly control the edges and corners from the LED splitting to obtain a square LED chip. The diameter of the surface hole 101 may be 5 to 15 m, and the diameter of the internal hole 102 may be 3 to 5 μm. In this embodiment, the surface hole 101 may be formed first and then the internal hole 102 is formed, or the internal hole 102 may be formed first and then the surface hole 101 is formed. The laser etching time is controlled, so as to prevent the heat energy generated during the laser dicing process from damaging the epitaxial layer of the chip and causing the electrical leakage phenomenon. It should be noted that, the surface holes 101 and the internal holes 102 may or may not be aligned.

The formation of the internal holes will be described in detail below with reference to FIG. 8 and FIG. 9. First, a laser beam is provided to focus inside the substrate 110, X scribe lines and surface holes 101A are formed on the same cross-section inside the substrate 110 along the first direction D1, and Y scribe lines (Y≥X≥1) and surface holes 101B are formed on the same cross-section inside the substrate along the second direction. Specifically, X first scribe lines 111 are formed on the same cross-section inside the substrate 110 along the first direction D1 using a laser beam of a first pulse energy, and the first scribe line 111 is a series of modified areas 103 formed by laser etching. In the middle of the modified area 103, there is a series of first explosion spots 102A formed by laser etching, which are internal holes 102, as shown in FIG. 9. Y second scribe lines 112 are formed on the same cross-section inside the substrate 110 along the second direction D2 using a laser beam of a second pulse energy. The second scribe line has a second explosion spot 102B formed by a series of laser etching, as shown in FIG. 10. In this embodiment, the first direction D1 corresponds to the hard-to-crack surface, so a laser beam of a large power is used to form at least one continuous first scribe line 111 inside the substrate, and the distance between the first scribe line 111 and the first surface S11 of the substrate 110 is preferably 15 μm or more to ensure that the epitaxial layer is not be damaged during the laser etching inside the substrate 110, for example, the distance may be 20 μm to 60 μm. When there are more than two first scribe lines 111, the spacing between adjacent first scribe lines 111 may be 10 to 50 μm. Preferably, the spacing between adjacent first explosion spots 102A positioned in the same column is preferably 1 μm or more and 12 μm or less, and the spacing may be 3 to 5 μm, 5 to 8 μm, or 8 to 12 μm. If the spacing is less than 1 μm, then the efficiency will be affected. If the spacing is more than 12 μm, then the first scribe line 111 may not be continuous, causing the subsequent splitting difficult. In this embodiment, the spacing is preferably 3 to 5 μm. The second direction D2 corresponds to the easy-to-crack surface, so a laser beam of a small power is used to form multiple non-continuous second scribe lines 112 inside the substrate 110. The distance D11 between the second scribe line 112 and the first surface of the substrate 110 is preferably 10 μm or more, preferably 15 to 50 μm. When the distance is small, on the one hand, the laser is likely to damage the epitaxial layer during the etching process of the substrate 110, and on the other hand, the cracks generated during the splitting process may also extend beyond the first surface S11 of the substrate 110 to reach the epitaxial layer, the insulation layer, or the electrode. When the distance is large, oblique cracking is likely to occur along the lattice direction of (1102) surface during the splitting process. The scribe line includes a series of second explosion spots 102B (the internal holes 102) spaced apart from each other and arranged relatively regularly. The spacing between two adjacent second explosion spots 102B is preferably 5 μm or more and 20 μm or less. In a specific embodiment, the spacing is 10 to 12 μm.

Referring to FIG. 10, in this embodiment, a thickness H10 of the substrate is preferably 80 to 200 μm, for example, the thickness may be 120 to 160 μm, a depth H11 of the surface hole 101 is preferably larger than 10 μm and less than 20 μm, and a length H12 of the internal hole 102 in the thickness direction is preferably ⅓×(H10−H11) to ¾×(H10−H11). It should be noted that, when multiple scribe lines are formed on the same dicing surface of the substrate 110, the length of the internal hole 102 in the thickness direction refers to the total length from the top scribe line to the bottom scribe line.

In a preferred embodiment, the thickness of the substrate is 80 to 200 μm. For the dicing surface (1010) close to the slip surface, that is, the dicing surface where the second direction D2 is positioned, a laser with a low power is used to perform multi-focus stealth dicing, the quantity of stealth dicing points is greater than or equal to 3 and less than or equal to 20. Stealth dicing of dense and small multi-points is used to form an approximately continuous multi-point dicing on the thickness direction of the same dicing surface, vertical destruction is performed at multiple points on the (1102) surface in the lattice direction, so that the cracks in the subsequent splitting process may crack along the (1010) direction, thereby achieving a vertical degree of 85 to 950 of the LED chip. Specifically, a laser beam is first provided to focus inside the substrate 110, X scribe lines are formed on the same cross-section inside the substrate along the first direction D1, and Y scribe lines are formed on the same cross-section inside the substrate along the second direction. In this embodiment, for the hard-to-crack surface, a laser beam with a larger power is used to form 1 to 10 scribe lines, preferably 2 to 5 lines. Forming merely one scribe line (i.e. single focus dicing) requires a laser beam with a higher power to perform etching, and the dicing marks formed at this time are difficult to control. On the one hand, twin crystal problems (two chips are not separated) may often occur during dicing, on the other hand, the cracks during the splitting process may easily reach the first surface of the substrate to damage the light-emitting semiconductor stacking structure, the insulation layer, or the electrode, causing the failure of the chip. The second direction D2 corresponds to the easy-to-crack surface, so a laser beam of a small power is used to form 2 to 20 scribe lines, preferably 5 to 16 lines, which can achieve a good vertical effect, and the appearance of the chip viewed from the top view is square and non-wavy. The distance between the position of the center line (i.e. focus) of the second scribe line 112 and the upper surface S11 of the substrate is preferably 5 μm or more, more preferably 15 μm or more, such as 16 μm, 20 μm, 30 μm, or 35 μm. When the distance is less than 5 μm, the texture formed by the laser etching or the cracks generated during the splitting process may easily reach the first surface of the substrate, thereby damaging the semiconductor light-emitting stack, the insulation layer, or the electrode, causing the failure of the LED chip. When the distance is more than 50 μm, the oblique cracks are likely to occur along (1102) during the splitting. Preferably, Y second scribe lines may be formed by using a single-blade multi-focus, so that on the one hand, the split appearance of the double lines can be avoided, and on the other hand, the efficiency of laser dicing can be improved.

Step S140: the LED wafer is separated into multiple LED chips along the dicing lanes. The top view of a single chip is as shown in FIG. 11. Referring to FIG. 12 and FIG. 13, the first side surface (corresponding to the first direction) of the formed LED chip has at least one first dicing mark 1110. The first dicing mark includes cracks 1113 extending upward and downward from the first scribe line. The second side surface of the LED chip (corresponding to the second dicing direction) has at least two parallel second dicing marks 1120 and horizontal cracks 113. The texture of the second dicing mark 1120 is relatively regular and thin compared with the texture of the first dicing mark 1110. In this embodiment, by controlling the distance between the first explosion spot and the upper surface S11 of the substrate, the first crack 1113 does not reach the first surface S11 of the substrate as much as possible, and the crack of the dicing mark 1113 close to the lower surface of the substrate ends at the first surface laser etching pattern (the surface hole 101A), the surface laser etching pattern is from the surface hole 101A shown in FIG. 9, being specifically a series of recesses extending from the second surface S12 of the substrate to the first surface of the substrate, and the depth of the recess is the depth of the surface hole 101A. The second side surface includes at least two second dicing marks 1120 parallel to each other. The second dicing mark 1120 includes a series of internal laser etching patterns 1121 (from the modified area formed inside the laser etching substrate) and cracks 1122 extending from the internal laser etching patterns 1121 in the upward and downward directions, the first dicing mark is close to the upper surface of the substrate. The distance between the explosion spot thereof and the upper surface S11 of the substrate is 20 to 60 μm. The second dicing mark is close to the lower surface of the substrate. The distance between the explosion spot thereof and the recess is 5 to 20 μm, such as 5 μm to 10 μm, in which the crack of the first dicing mark does not reach the first surface S11 of the substrate, and the size is smaller than the size of the crack of the second dicing mark. The crack 1122 of the second dicing mark extends to the second surface of the substrate and ends at the second surface laser etching pattern (the surface hole 101B), the second surface laser etching pattern is from the second explosion spot 102B, which is specifically a series of recessed structures. Furthermore, the horizontal crack 113 is included below the first dicing mark 112, and the crack 1122 of the first dicing mark extends toward the second surface of the substrate and ends at the horizontal crack 113.

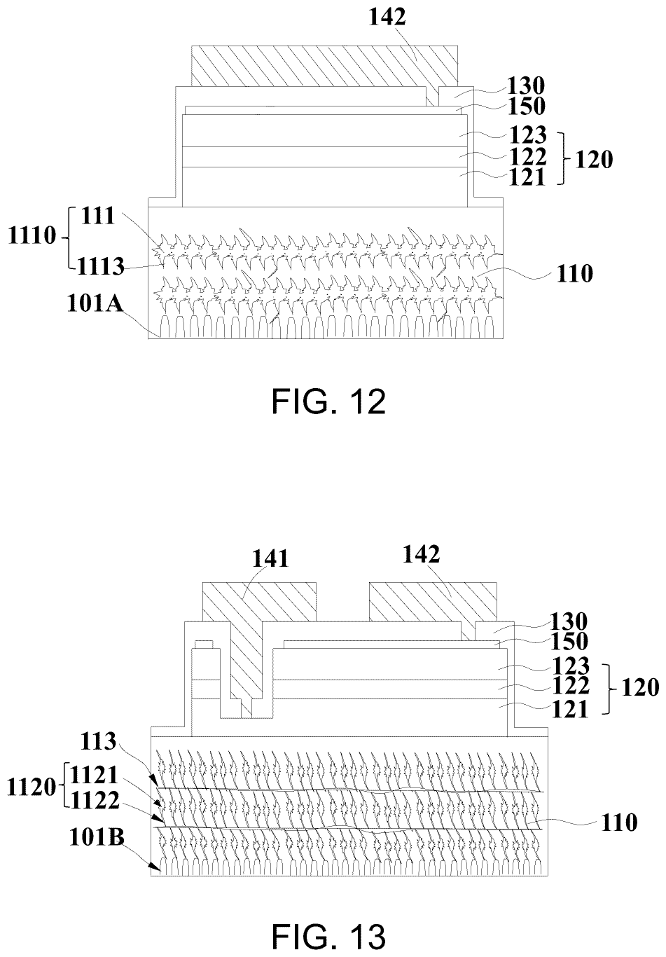

FIG. 14 shows a photo of the LED chip formed by splitting the LED wafer. It may be seen that each LED chip is distributed in a rectangular shape, and the edges are not significantly distorted. From the partial enlargement view of the edge of the chip, it may be seen that there is no chipping or oblique cracks on the back of the substrate. FIG. 15 shows the light distribution curve diagram of the LED chip, which has a symmetrical light pattern.

Referring again to FIG. 11, which is a top view of an LED chip implemented according to the invention, which is a rectangular or square flip-chip type LED chip. The LED chip includes the following stacked layers: the substrate 110, the light-emitting semiconductor stacking structure, the insulation layer 130, the first electrode 141, and the second electrode 142. The substrate 110 includes four sides A1 to A4 surrounding clockwise, in which the side A1 and the side A3 are parallel and are the short sides, and the side A2 and the side A4 are parallel and are the long sides. The LED chip may be a small-sized LED chip with a small horizontal area. For example, it may have a horizontal cross-sectional area of approximately 62500 μm² or less, and further may have a horizontal cross-sectional area of approximately 900 μm² or more and approximately 62500 μm² or less, the size of the LED chip may be reflected by the size of the first surface of the substrate, for example, the side length of the first surface of the substrate 110 is preferably less than or equal to 300 μm, preferably from 200 to 300 μm, or from 100 to 200 μm, or a size of 100 μm or less, preferably from 30 to 150 μm. The thickness of the substrate 110 is preferably 30 to 160 μm, such as 50 to 80 μm, 80 to 120 μm, and 120 to 160 μm. The thickness of the light-emitting semiconductor stacking structure is from 4 to 10 μm. The light-emitting diode of the embodiment has the above-mentioned size and thickness, so the LED chip can be easily applied to various electronic devices requiring small and/or thin light-emitting devices. FIG. 12 shows the side surface corresponding to the side A1 or the side A3 of the substrate 110 of an LED chip implemented according to the invention, the side surface of the substrate includes at least one first dicing mark 1110. FIG. 13 shows the side surface corresponding to the side A2 or side A4 of the substrate 110, including at least two parallel second dicing marks 1120 and a horizontal crack 113 positioned below the first second dicing mark 1120. It may be seen from the drawing that the size and roughness of the first dicing mark 1110 are larger than the size and roughness of the second dicing mark 1120, that is, the first dicing mark 1110 is thicker than the second dicing mark 1120. Specifically, the size is greater in the thickness direction of the substrate, the depth is greater in the thickness direction of the substrate, and the shape of the first dicing mark is formed in a vertically irregular jagged shape. The second dicing marks include a series of textures with equal spacings, and there is a horizontal crack 113 between two adjacent second dicing marks. In this embodiment, for the hard-to-crack surface where the edge A1 and the edge A3 are positioned, a large modified portion is formed inside the substrate to ensure the subsequent splitting is carried out smoothly and avoid possible twin crystal problems (two chips are not separated). For the easy-to-crack surface where the edge A2 and the edge A4 are positioned, a small modified portion is formed inside the substrate to prevent the cracks from extending to the upper surface of the substrate during the subsequent splitting process and damaging the semiconductor epitaxial stack structure or the electrode, causing the failure of the chip.

In a specific implementation of this embodiment, the upper area of the second side surface of the substrate 110 of the LED chip is a flat area, and the middle area and the lower area of the second side surface of the substrate 110 of the LED chip are roughened areas occupied by the second dicing mark 1120, the horizontal crack 113, and the surface laser etching pattern, and the adjacent second dicing marks 1120 basically reach the horizontal crack 113 therebetween, forming an approximately continuous longitudinal scribe line (the thickness direction), in which the area of the roughened area accounts for more than 60% of the area of the side surface, preferably 60% to 85%. On the one hand, the risk of electrical leakage (laser dicing or splitting damages the functional layers of the LED) can be reduced. On the other hand, due to the substrate having translucent quality and a great thickness, it is beneficial for the light emitted by the active layer of the LED chip to be extracted from the side surface, thereby increasing the light extraction efficiency.

Further, the insulation layer 130 is an insulating reflective layer that covers the top surface and side walls of the light-emitting semiconductor stacking structure. When the light radiated by the light-emitting layer reaches the surface of the insulation layer 130 through the contact electrode 150, most light can be reflected by the insulation layer 130 to be returned to the light-emitting semiconductor stacking structure, and most of the light passes through the second surface side of the substrate, reducing light loss caused by light passing through the surface and side walls of the light-emitting semiconductor stacking structure. Preferably, the insulation layer 130 can reflect at least 80% or further at least 90% of the light intensity of the light radiated by the light-emitting layer reaching the surface thereof. The insulation layer 130 may specifically include a Bragg reflector. The Bragg reflector may be formed by repeatedly stacking at least two insulating media with different refractive indexes, and may be formed from 4 pairs to 20 pairs. For example, the insulation layer may include TiO₂, SiO₂, HfO₂, ZrO₂, Nb₂O₅, MgF₂, etc. In some embodiments, the insulation layer 130 may alternately deposit TiO₂ layers/SiO₂ layers. Each layer of the Bragg reflector may have an optical thickness that is ¼ of the peak wavelength of the radiation band of the light-emitting layer. The uppermost layer of the Bragg reflector may be formed of SiNx. The layer formed of SiNx has excellent moisture resistance and protects the light-emitting diode from moisture. In the case where the insulation layer 130 includes the Bragg reflector, the lowermost layer of the insulation layer 130 may have a bottom layer or an interface layer that improves the film quality of the distributed Bragg reflector. For example, the insulation layer 130 may include an interface layer formed of SiO₂ with a thickness of approximately 0.2 to 1.0 μm and layers of TiO₂/SiO₂ stacked according to a specific period on the interface layer.

In some embodiments, the insulation layer 130 may also be just a single insulation layer, preferably, the reflectivity is generally lower than the Bragg reflection layer, and at least 40% of the light is emitted from the insulation layer 130. Preferably, the thickness is at least 1 μm or more preferably 2 μm or more, such as SiO₂, which has excellent moisture resistance and can protect the light-emitting diode from moisture.

The contact electrode 150 may make ohmic contact with the second conductivity type semiconductor layer 123. The contact electrode 150 may include a transparent conductive layer. The transparent conductive layer may also include, for example, at least one of a translucent conductive oxide such as indium tin oxide, zinc oxide, zinc indium tin oxide, indium zinc oxide, zinc tin oxide, gallium indium tin oxide, indium gallium oxide, zinc gallium oxide, aluminum doped zinc oxide, fluorine doped tin oxide and a translucent metal layer such as Ni/Au. The conductive oxide may also include various dopants. Preferably, the thickness of the contact electrode 150 is 20 to 300 nm. The surface contact resistances of the contact electrode 150 and the second conductivity type semiconductor layer 123 are preferably lower than the surface contact resistance of the metal electrode on the second conductivity type semiconductor layer 123, so that the forward voltage can be reduced, and the light-emitting efficiency is improved.

The first electrode 141 and the second electrode 142 have a multi-layer structure, and the bottom layer is one or more laminated combinations of metal materials of Cr, A1, Ti, Ni, Pt, and Au. In some embodiments, the surface layers of the first and second electrodes are Sn-containing metal materials. In other embodiments, the surface layers of the first and second electrodes may also be Au metal materials.

In a specific implementation of this embodiment, a reflective layer may also be provided on the second surface side of the substrate. The reflective layer may be a single-layer or multi-layer structure, which can increase the light-emitting angle of the LED chip, and the light-emitting angle thereof may reach more than 160°, which can be applied to the backlight module of a display device. Through disposing a reflective layer on the second surface of the substrate of the LED chip, the light emission path of the LED chip is changed and the light-emitting angle of the LED chip is increased, which is beneficial to reducing the thickness of the backlight module and reducing the size of the backlight module. The reflective layer at least covers the middle area of the second surface of the substrate 110, and may also completely cover the second surface of the substrate. Preferably, the reflective layer is an insulating reflective layer, which can be formed by alternately stacking high and low refractive index materials, for example, alternately stacking SiO₂ and TiO₂.

In a specific implementation of this embodiment, different laser energies may be used to form dicing marks on different side surfaces during the dicing process, for example, for the dicing surface positioned at the hard-to-crack surface, a laser beam with a large pulse energy is used to form a large modified portion inside the substrate to ensure that the subsequent splitting is carried out smoothly and avoiding the twin crystal problem (two chips are not separated) that often occurs during dicing, for the dicing surface positioned at the easy-to-crack surface, a laser beam with a small pulse energy is used to form a small modified portion inside the substrate to prevent the cracks from extending to the upper surface of the substrate during the subsequent splitting process and damaging the semiconductor stacking structure or the electrode, causing the failure of the chip.

In another specific implementation of this embodiment, different quantities of the dicing marks may be formed on different side surfaces of the substrate. A small number of dicing marks (for example, 2 to 5) may be formed on the dicing surface positioned at the hard-to-crack surface, which is beneficial to forming a large modified portion inside the substrate by using a laser beam with a large pulse energy in this area to prevent the dicing marks from extending to the light-emitting epitaxial structure that damages the epitaxial structure or the electrode, causing the failure of the chip. A larger number of dicing marks (for example, 5 to 20) are formed on the dicing surface positioned at the easy-to-crack surface, and an approximately continuous longitudinal scribe line is formed in the thickness direction of the substrate, and then vertical destruction is performed at multiple points in the (1102) lattice direction, so as to prevent the cracks from cracking along the slip surface (1102) direction during the splitting process, thereby a substantially vertical side wall is obtained.

### Embodiment 2

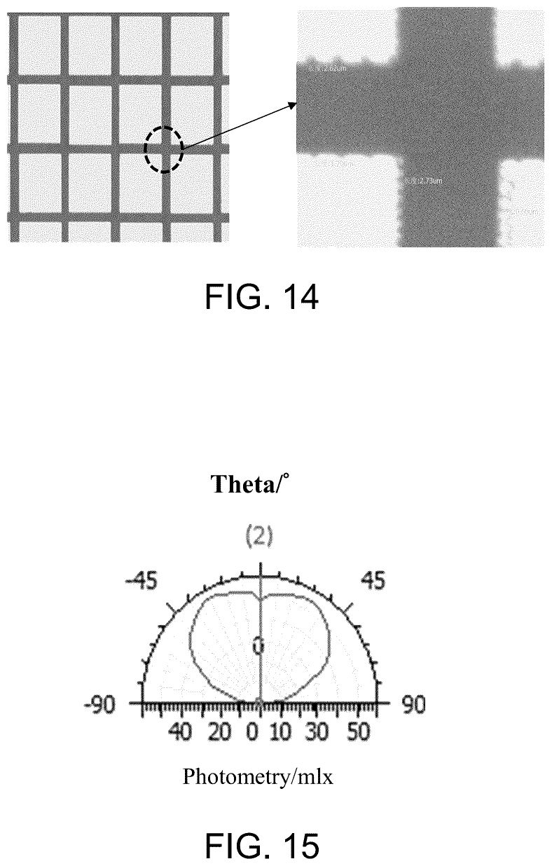

FIG. 16 shows a schematic structural diagram of an LED chip implemented according to the invention. The difference from the LED chip shown in Embodiment 1 is: at least three columns of dicing marks are formed on the hard-to-crack surface of the substrate by using a laser beam of a low power, and the series of dicing marks may be non-connected or connected, but basically are not intersected with each other. The dicing mark 1110 close to the first and second surfaces of the substrate are jagged, having a series of explosion spots and cracks 1111 extending from the explosion spots to the first surface and second surface. The dicing mark 1112 in the middle area is a series of explosion spots formed by laser etching.

In the embodiment, the hard-to-crack surface formed in this manner forms a fine and densely packed concave-convex structure, and the area ratio of the concave-convex structure on the side surface can reach more than 50%, which is beneficial to performing the dicing of the chip and reducing the risk of damaging the functional layers of the chip on the one hand and is beneficial to increasing the light extraction efficiency from the side of the substrate of the LED chip on the other hand.

### Embodiment 3

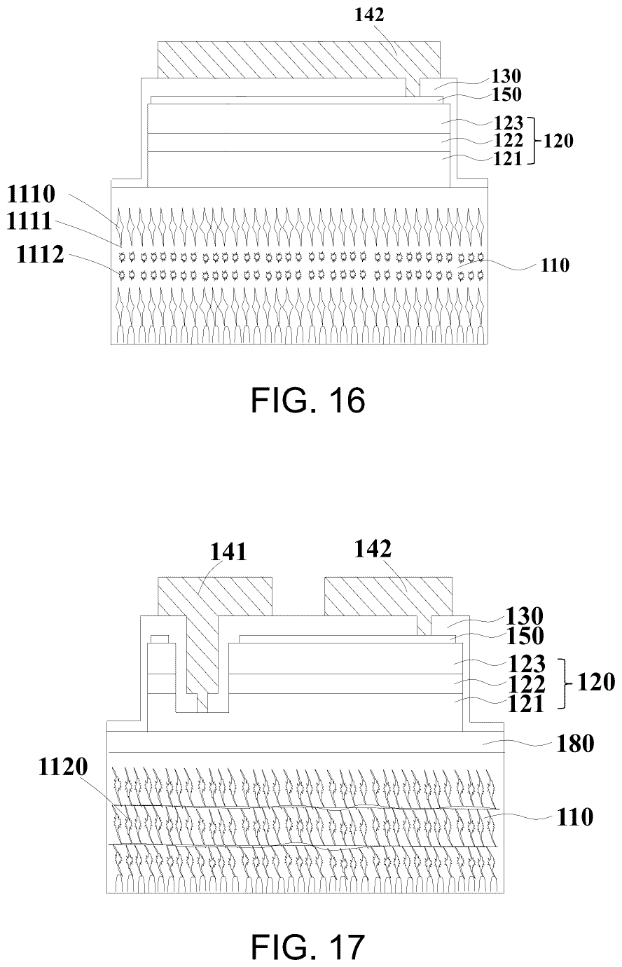

FIG. 17 shows a schematic structural diagram of an LED chip implemented according to the invention. The light-emitting semiconductor stacking structure 120 of the LED chip shown in the previous embodiments is formed on the substrate 110 through epitaxial growth. In this embodiment, the light-emitting semiconductor stacking structure 120 is formed on the substrate 110 through a bonding layer 180. In a specific embodiment, the light-emitting semiconductor stacking structure 120 is an AlGaInP-based semiconductor layer, and the AlGaInP-based epitaxial structure is first grown on the gallium arsenide substrate, and then the AlGaInP-based epitaxial structure is transferred to the transparent substrate 110.

### Embodiment 4

This embodiment discloses a deep ultraviolet LED chip, in which the thickness of the substrate 110 is 200 to 750 μm, so the easy-to-crack surface requires multiple-blade and multi-focus laser dicing. In a specific embodiment, the thickness of the substrate of the LED chip is 400 to 450 μm. At this time, the dicing is performed by using a single-blade 9-focus laser beam in the first direction (the hard-to-crack surface), and the dicing is performed by using a 3-blade 9-focus laser beam in the second direction (the easy-to-crack surface). In another specific embodiment, the thickness of the substrate is more than 500 μm, so the dicing is performed by using a 3-blade 9-focus laser beam in the first direction (the hard-to-crack surface), and the dicing is performed by using a 5-blade 9-focus laser beam in the second direction (the easy-to-crack surface).

What is claimed is:

1. A manufacturing method of a light-emitting diode, comprising:
providing an LED wafer, wherein the LED wafer comprises a substrate and a light-emitting semiconductor stacking structure positioned on an upper surface of the substrate, the light-emitting semiconductor stacking structure comprises a first type semiconductor layer, an active layer, and a second type semiconductor layer from a side of the substrate;
defining dicing lanes on an upper surface of the LED wafer;
dicing is performed along the dicing lanes of the substrate using a laser: focusing the laser on a lower surface of the substrate to form a surface hole, and focusing the laser inside the substrate to form an internal hole, wherein a diameter of the surface hole is greater than a diameter of the internal hole, the diameter of the surface hole is 5 to 15 μm, and the diameter of the internal hole is 3 to 5 μm; and
separating the LED wafer into a plurality of LED chips along the dicing lanes.

2. The manufacturing method of the light-emitting diode as claimed in claim 1, wherein a depth of the surface hole is 1/10 to ⅕ of a thickness of the substrate.

3. The manufacturing method of the light-emitting diode as claimed in claim 1, wherein, the dicing lanes defined in the second step comprise a first direction and a second direction, the first direction is perpendicular to the second direction, wherein in the third step, X scribe lines are formed on same cross-section inside the substrate along the first direction using a first laser beam, and Y scribe lines are formed on same cross-section inside the substrate along the second direction using a second laser beam, wherein a pulse energy of the first laser beam is greater than a pulse energy of the second laser beam.

4. The manufacturing method of the light-emitting diode as claimed in claim 3, wherein 1≤X≤5.

5. The manufacturing method of the light-emitting diode as claimed in claim 3, wherein 2≤Y≤20.

6. The manufacturing method of the light-emitting diode as claimed in claim 1, wherein in the LED chip formed in the manufacturing method, an angle between a side wall of the substrate and the upper surface of the substrate is 85 to 95°.

7. The manufacturing method of the light-emitting diode as claimed in claim 1, wherein a thickness of the substrate is greater than or equal to 80 μm and less than or equal to 200 μm, or greater than 200 μm and less than or equal to 750 μm.

8. The manufacturing method of the light-emitting diode as claimed in claim 1, wherein a distance between the internal hole and the upper surface of the substrate is greater than or equal to 10 μm.

9. The manufacturing method of the light-emitting diode as claimed in claim 1, wherein a spacing is between the surface hole and the internal hole.

10. A light-emitting diode, comprising a substrate and a light-emitting semiconductor stacking structure positioned on an upper surface of the substrate, wherein the light-emitting semiconductor stacking structure comprises a first type semiconductor layer, an active layer, and a second type semiconductor layer from a side of the substrate, at least one side surface of the substrate comprises a surface laser etching pattern and an internal laser etching pattern, the surface laser etching pattern is a series of recesses extending from a lower surface of the substrate to the upper surface, the internal laser etching pattern comprises a series of explosion spots formed by laser etching, diameters of the recesses perpendicular to a thickness direction are greater than diameters of the explosion spots perpendicular to the thickness direction, the light-emitting diode is formed by separating an LED wafer along dicing lanes, the dicing lanes are distributed with a series of surface holes, the recesses are formed in response to the LED wafer being separated to form the light-emitting diode, and diameters of the surface holes are 5 to 15 μm.

11. The light-emitting diode as claimed in claim 10, wherein the at least one side surface comprises a crack connected to the internal laser etching pattern, and the crack extends toward the upper surface and the lower surface of the substrate.

12. The light-emitting diode as claimed in claim 11, wherein a portion of the crack extends toward the lower surface of the substrate and ends at the surface laser etching pattern.

13. The light-emitting diode as claimed in claim 11, wherein the at least one side surface comprises at least two columns of internal laser etching patterns and a horizontal crack positioned between the two columns of internal laser etching patterns.

14. The light-emitting diode as claimed in claim 10, wherein a depth of the surface laser etching pattern is 1/10 to ⅕ of a thickness of the substrate.

15. The light-emitting diode as claimed in claim 10, wherein a spacing is between the internal laser etching pattern and the surface laser etching pattern.

16. The light-emitting diode as claimed in claim 10, wherein an angle between a side surface of the substrate and the upper surface of the substrate is 85 to 95°.

17. The light-emitting diode as claimed in claim 10, wherein a side length of at least one edge of the upper surface of the substrate is of 200 to 300 μm, 100 to 200 μm, or 40 to 100 μm.

18. The light-emitting diode as claimed in claim 10, wherein the substrate comprises a first side surface and a second side surface adjacent to each other, the first side surface has X first internal laser etching patterns arranged horizontally, and the second side surface has Y second internal laser etching patterns arranged horizontally, wherein Y>X>0, and Y≥2.

19. The light-emitting diode as claimed in claim 18, wherein a roughness of the first internal laser etching pattern is greater than a roughness of the second internal laser etching pattern.

20. The light-emitting diode as claimed in claim 10, wherein a distance between the internal laser etching pattern and the upper surface of the substrate is greater than or equal to 10 μm.
